(19) United States
(12) Patent Application Publication
(10) Pub. No.: US 2011/0175612 A1
(43) Pub. Date: Jul. 21, 2011

(54) MAGNETIC RESONANCE IMAGING WITH INDEPENDENT EXCITATION AND ACQUISITION VOLUMES

(76) Inventors: Amir EISSA, Edmonton (CA); Alan H. WILMAN, Edmonton (CA)

(21) Appl. No.: 13/006,003

(22) Filed: Jan. 13, 2011

Related U.S. Application Data
(60) Provisional application No. 61/294,702, filed on Jan. 13, 2010.

(51) Int. Cl. G01R 33/48

(52) U.S. Cl. 324/309

(57) ABSTRACT

A method of magnetic resonance that uses non-aligned slab excitation and encoding. By separating the directions of slab excitation and slab phase encoding, the method may allow voxel orientation that is independent of the excitation direction. Accordingly, volume excitation may be chosen based on anatomical landmarks which are not aligned in the excitation direction.

### CROSS REFERENCE TO RELATED APPLICATIONS

This application claims the priority benefit of U.S. Provisional Patent Application No. 61/294,702 filed on Jan. 13, 2010 entitled “Magnetic Resonance Imaging With Independent Excitation and Acquisition Volumes With Application To Oblique SWI, the contents of which are incorporated herein by reference.

### FIELD OF THE INVENTION

The present invention relates to methods of magnetic resonance imaging.

### BACKGROUND

Magnetic resonance imaging (MRI) is a medical imaging technique used to visualize detailed internal structure of the body. The majority of MR images are typically created by two-dimensional or three-dimensional Fourier transform techniques.

In its most basic form, MR imaging measures nuclear spin density throughout a sample. Image intensity is typically proportional to the number of observed nuclear spins and other relaxation properties.

A technique for enhancing image contrast in MRI is described in “Artery and Vein Separation Using Susceptibility-Dependent Phase in Contrast-Enhanced MRA”, Wang et al., Journal of Magnetic Resonance Imaging, 12:661-670 (2000), the entire contents of which is incorporated herein by reference (where permitted). In this technique, both magnitude and phase images are obtained using a gradient echo sequence. The magnitude image is operated upon using a mask computed from the phase image.

Conventionally, the current practice of two-dimensional (2D) and three-dimensional (3D) MR Imaging applies the read out data acquisition in a direction orthogonal to that of slice selection and/or slice encoding. In 3D MRI, the slice encoding direction is typically aligned with the slice selection direction.

A method of MRI, known as susceptibility weighted imaging (SWI) was recently described in U.S. Pat. No. 6,658,280, the entire contents of which are incorporated herein by reference, where permitted. To obtain good contrast from a phase/SWI image, a rod shaped voxel is preferred with the longer dimension lying parallel to the static field which entails the common practice in SWI applications of applying high in plane resolution and thick slices. Adding up phase along the field direction increases the sensitivity in the resulting image to phase variation within the voxel as it has a more coherent phase sign. In the extreme case of a voxel with its long dimension lying perpendicular to the magnetic field, the phase sign could be completely reversed. This implies phase cancellation and other erratic behaviors for voxels at varying angles with the magnetic field. This effect is more noticeable in heterogenous voxels encompassing different tissue types as in the case of smaller veins as well as boundaries between different structures.

SWI techniques are challenged by the need to ensure that the acquired imaging voxel is aligned with the static field. This orientation dependence arises from the manner in which the field perturbations arise around a magnetic dipole aligned with the main field where a rectangular area aligned with the dipole will have a pattern of phase/field summation drastically different from the same summation when applied to a rectangular area that has a non-zero angle with the dipole direction.

The orientational effects of the dipole field present a significant limitation on quantitative phase measures and SWI because of the dependence on the main magnetic field direction. The field within and around a paramagnetic (or ferromagnetic) cylinder can be estimated based on the following Equations 1 and 2.

$$\begin{matrix}Δ {B}_{in} = - 4 π C χ {B}_{o} / 3 & [ 1 ] \\ Δ {B}_{out} = 4 π C χ cos 2 φ ( \frac{{r}^{2}}{{ρ}^{2}} ) {B}_{o} & [ 2 ]\end{matrix}$$

where ΔBᵢₙ is the intravascular field difference, ΔBₒᵤₜ the extravascular field difference, χ is the susceptibility difference between deoxyhemoglobin and it surrounding tissue, Bₒ is the static field strength, C is a constant that contains other non-directional factors, ρ is the distance between the position considered and the center of the blood vessel, φ is the polar angle between the considered position/distance (ρ) and the static field and r is the vessel radius.

Due to the “cos 2φ” dependence, the dipole field has strong positive effects along the main magnetic field and strong negative effects perpendicular to the main field with the variable “cos 2φ” dependence for angles in-between. If an imaging voxel is aligned with the magnetic field, the phase effects will sum up to give a positive average value for the voxel containing the cylinder. If the voxel is angled, the summation may lead to cancellation due to negative and positive additions. This is a major limitation when slight variations in patient positioning may demand an altered scan prescription. Therefore, current phase and SWI methods do not enable accurate imaging with oblique slice orientation. In addition, a common practice in clinical brain studies is to align the imaging slab with the anterior commissure to posterior commisure (ACPC) line. The orientation of the ACPC line with the main magnetic field can vary substantially between individuals.

More generally, many MRI applications may benefit from a preferential voxel alignment direction whereby the imaging method can arbitrarily control the direction of maximum spatial resolution within the encoding volume.

### SUMMARY OF THE INVENTION

In general terms, embodiments of the present invention seek to separate the image acquisition volume from the excitation volume to enable any angle of separation between them. Three dimensional imaging is typically performed with the same orientation for RF slab excitation and slab select phase encoding. The present invention implements a novel approach to 3D imaging that uses independent slab excitation and encoding. By separating the directions of slab excitation and slab phase encoding, the method may allow voxel orientation that is independent of the excitation direction. In one embodiment, the method comprises simple pulse sequence modifications, and uses standard image reconstruction followed by correction of aliasing and image reformatting. In one embodiment, this method enables oblique imaging with voxel encoding aligned with the main magnetic field, which enables accurate obliquely oriented susceptibility phase images, without the confounds of obliquely directed voxels that currently limit this method.

Therefore, in one aspect, the invention comprises a three-dimensional MR imaging method, comprising the steps of:
(a) selecting an excitation volume which is not aligned with an acquisition volume, creating an angle between them;
(b) adjusting a slice encoding field of view to account for said angle;
(c) acquiring the MR image; and
(d) reformatting the image to sort aliased portions when present and to preserve proper scale.
   In another aspect, the invention comprises a two-dimensional or three-dimensional magnetic resonance imaging method comprising the steps of:
(a) selecting a frequency encoding direction which is non-orthogonal and non-parallel with the slice selection direction, creating an angle between them;
(b) if the method is three-dimensional, adjusting a slice-encoding field of view to account for the angle;
(c) acquiring the MR image; and
(d) reformatting the image to sort aliased portions when present, and to preserve proper scale.

### BRIEF DESCRIPTION OF THE DRAWINGS

In the drawings, like elements are assigned like reference numerals. The drawings are not necessarily to scale, with the emphasis instead placed upon the principles of the present invention. Additionally, each of the embodiments depicted are but one of a number of possible arrangements utilizing the fundamental concepts of the present invention. The drawings are briefly described as follows:

FIG. 1A is a schematic showing the slab excitation volume (solid line) and the image data acquisition volume (dashed line) for a 3-D method. The slice encoding thickness of the imaging volume is thicker than that of the excitation volume. Points O and P show example of two data points that might overlap when aliasing happens. The horizontal lines within the image acquisition volume mark different image vectors of data where A is aliased from above the imaging slab, B is positioned in the imaging slab properly with no mapping and C is mapped from excited sample area below the imaging slab. FIG. 1B is a schematic showing the slab/slice excitation volume (solid line) and the image data acquisition volume for a 2-D method. The area marked with “a” shows an example voxel acquired using the traditional method (the solid box as the acquisition volume) while the area marked with “b” shows an example voxel acquired using the dashed box as the acquisition volume.

FIG. 2 shows an example pulse sequence diagram for independent slab selection and acquisition. This example sequence is essentially the same as a slice selection and read out flow compensated 3D Gradient Echo sequence. However, the slab selection gradient as well as its corresponding flow compensation is now distributed amongst both the frequency encoding (X) and slice phase encoding (Z) directions according to the angle required between the acquisition volume and the slice selection slab.

FIG. 3 shows a result using one embodiment of the inventive method. The three sub-slices shown in the image as A, B and C represent same corresponding lines from FIG. 1. The tilted rectangle shows the original slab excitation volume and the arrows from the shown image point to the original location where each of the sub-slices came from in the original sample geometry. This suggests the way image data points can be mapped back to their respective proper locations.

FIG. 4 shows additional phantom results depicting an acquired aliased image slice (left) and a corrected slice from the same dataset (right).

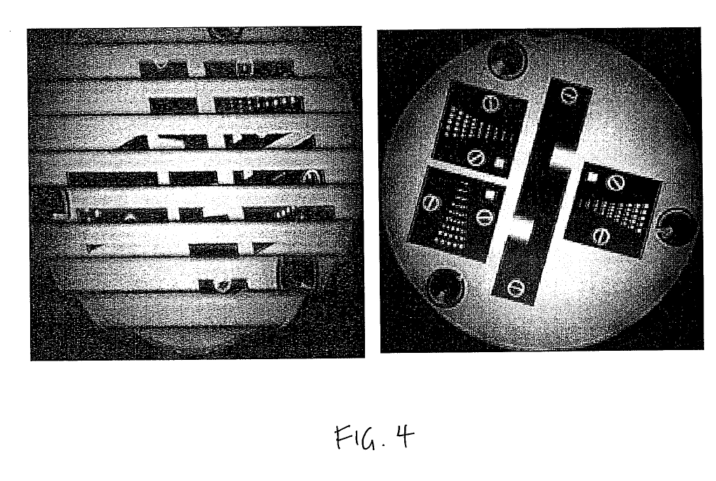

FIG. 5 shows a sagittal view where oblique slab selection was performed at an angle different from slice phase encoding. Slab selection is noted by the tilted solid rectangle in (a) and as marked in (b) while the acquisition slab is noted by the dashed rectangle in (a) and as marked (Z-Phase Encode) in (b). The larger solid rectangle in (a) shows the alternative slab thickness needed to image the required area of the brain in the traditional axial manner. The numbered areas in (b) show the different segments of the image within the excitation volume (N_{SS}) and in the acquired image (N_{Acq}). Only segment 1 is placed properly in the resulting image while the other segments require rearrangement.

FIG. 6A is a schematic of the acquired image lined by dashed rectangle and the slab excitation volume outlined in thick line. The 3D image is repeatedly stacked on top of itself to connect the segments numbered 7,5,3,1,2,4,6 as shown. All repeated segments shown by thin lines are then discarded. FIGS. 6B-E show the same concept applied to another imaging case where the geometry is different and the stacking process is repeated only three times because the left segments of the acquired image lie either in air or unimportant anatomy (outside the brain). FIG. 6B shows a human image example where the sagittal view of the acquired image is shown (corresponding to the dashed box in FIG. 6A). FIG. 6C shows three sets of the same image from FIG. 6B stacked on top of each other. FIG. 6D shows the same image from FIG. 6C after discarding unnecessary aliases. FIG. 6E shows the result from FIG. 6D after overlaying it on an inverted sagittal image from the same volunteer.

FIG. 7 is a schematic showing a magnification of the lower left corner in FIG. 6A to show different significant dimensions relating to slab thickness determination and the remapping process. To prevent irreversible aliasing in the Z direction, a new value is applied to the Z field of view to match the distance between slab selection volume edges measured in the direction of planned acquisition (vertical line marked with “thk/cos θ”).

FIG. 8 shows a flow chart showing steps in one embodiment of the method.

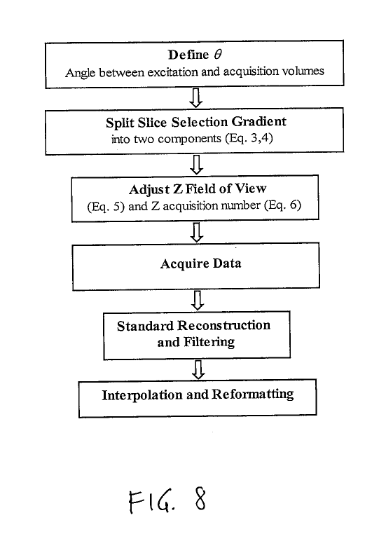

### DETAILED DESCRIPTION OF PREFERRED EMBODIMENTS

The invention relates to a method of magnetic resonance imaging. When describing the present invention, all terms not defined herein have their common art-recognized meanings. To the extent that the following description is of a specific embodiment or a particular use of the invention, it is intended to be illustrative only, and not limiting of the claimed invention. The following description is intended to cover all alternatives, modifications and equivalents that are included in the spirit and scope of the invention, as defined in the appended claims.

The present invention comprises a method that, in one embodiment, has been explained for 3D imaging with the application to allow for preferred transverse encoding for SWI phase summation parallel to the main magnetic field, yet allow for oblique angle excitations.

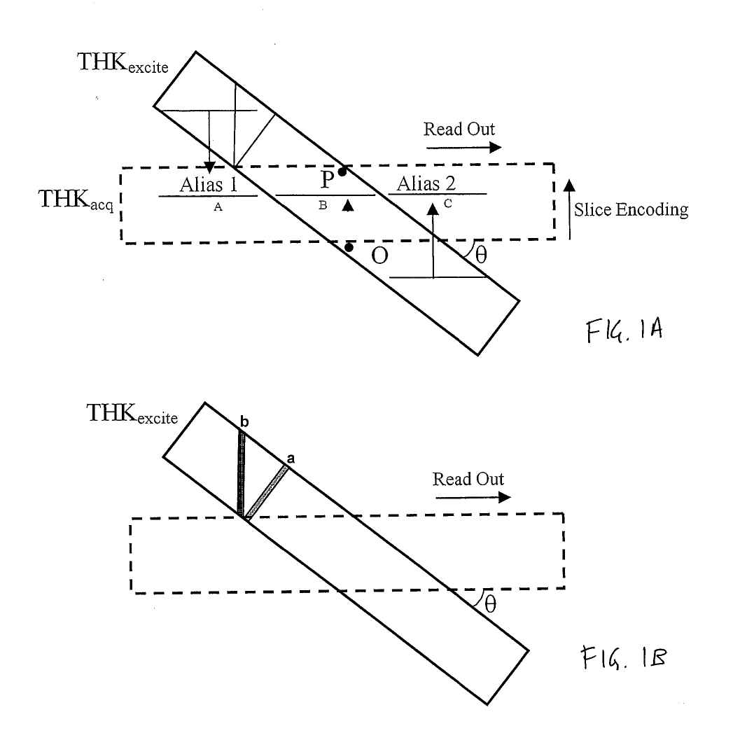

In one embodiment, the method comprises the step of applying slab excitation and image acquisition at independent angles. This concept is illustrated by an example in FIG. 1 where the slab excitation volume is applied to the rectangular area (10) outlined by a solid line. The acquisition volume (12) however, is illustrated by the rectangle outlined by a dashed line.

As seen in FIG. 1A, the long axis of the acquisition volume (12) is conventionally defined by the read out direction (the frequency encoding direction), which is conventionally orthogonal to the slice selection direction (and slice encoding direction in 3D applications). In the present invention, the excitation volume is selected to be non-aligned with the acquisition volume, creating angle θ. In other words, the slice selection direction is not aligned with the slice encoding direction, and is non-orthogonal with the read out or frequency encoding direction. In one embodiment, these concepts apply where the image encoding volume has a rectangular cross section.

As will be apparent to one skilled in the art, as a result of the creation of angle θ, the main axis of the image voxels is arbitrarily aligned at an angle of choice within the excitation volume, and is in non-parallel and non-orthogonal alignment with the slice selection direction. As used herein, the term “voxel” is a volumetric pixel or a volume element representing a value on a regular grid in three dimensions.

It is well known that imaging signal picked up by the reception coil(s) from outside the prescribed FOV(s) gets mapped to a different or erroneous location within the imaging volume, a phenomenon referred to as aliasing. It is generally an undesirable quality in most imaging applications and can happen despite proper placement of imaging volume and RF excitation. However, in the methods described herein, aliasing is part of the data collection process where if the aliased data are mapped to an area where no other data exist, it will be easily reversible through a simple re-mapping process. However, if aliasing causes any overlap of imaging data, the affected area of the image can be irreversibly damaged. To allow aliasing of data points only to a location where no other data exist, the slab thickness of the acquisition volume will be changed accordingly.

The present invention applies as well to 2D imaging where the slice selection can be applied at an angle different from that of the acquisition volume in the same manner as above with the exception that no slice encoding is applied and no aliasing will happen (FIG. 1B).

To apply this method, in one embodiment, the 3D Gradient Echo pulse sequence is varied. The main change in the pulse sequence is separating the slice selection gradient into two components in the X and Z directions, which are determined by the angle θ between the slab selection plane and the acquisition plane:

G_{X}=G_{SS} sin(θ) [3]

G_{Z}=G_{SS} cos(θ) [4]

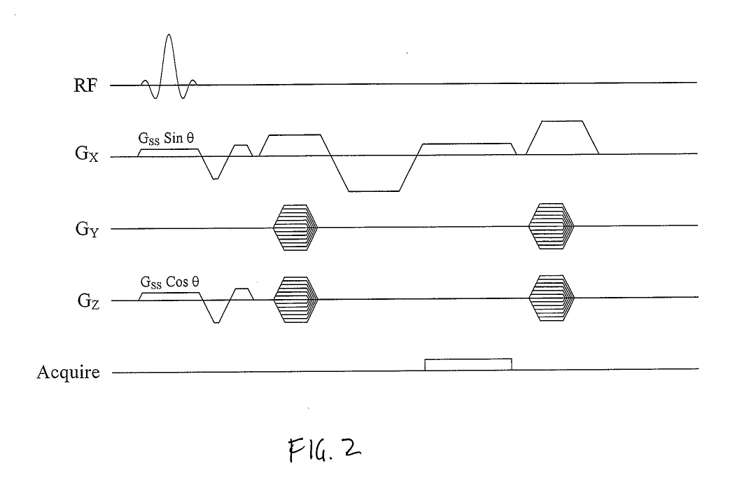

G_{X} and G_{Z} mark the read out and slice selection gradients respectively. This applies to the general case “logical” X and Z gradients. G_{SS} is the slice select gradient as set up for the specific excitation slab thickness. An exemplary pulse sequence diagram is shown in FIG. 2.

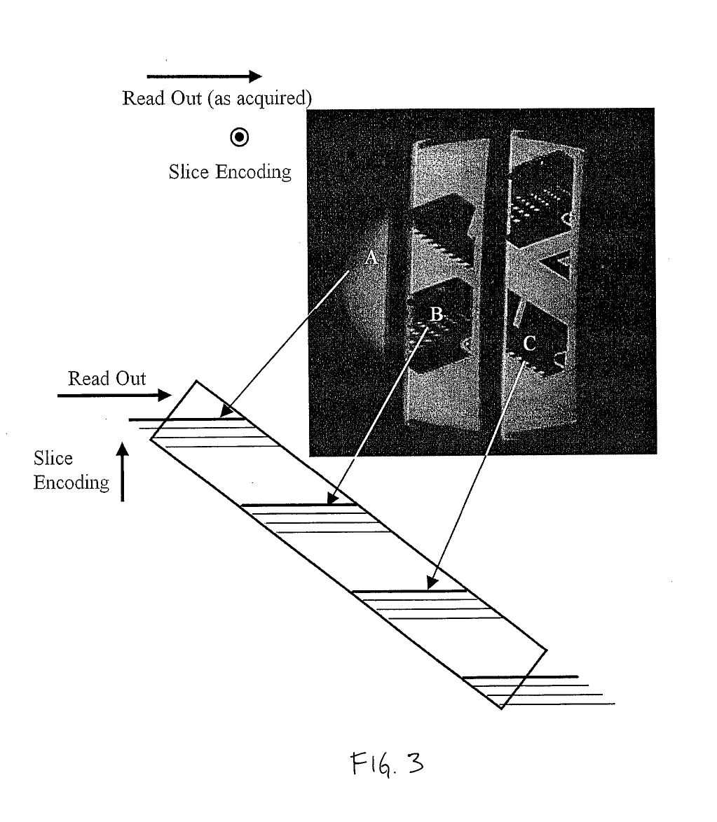

To validate the method for 3D imaging, phantom experiments were conducted using the above shown pulse sequence. To further visualize the process, a slice of an image set collected from a phantom is shown in FIG. 3. It resembles the plan shown in FIG. 1A where the A and C markings on the image also represent areas aliased from outside the imaging volume.

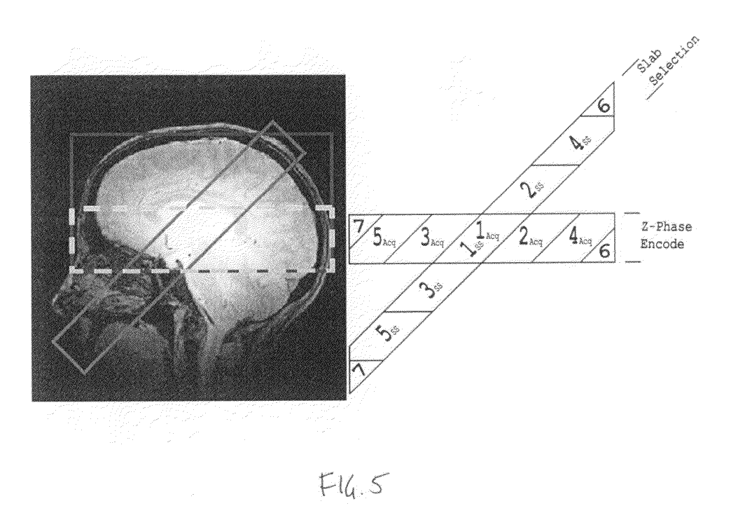

As an example for this application, we assume an oblique image is needed of the brain, which is at a 45 degrees angle with the anterior-posterior direction. This can best be illustrated in a sagittal view showing slab selection volume as well as the image acquisition volume at the stated angle as shown in FIG. 5. On applying a modified pulse sequence, most of the signal comes from outside the imaging/acquisition volume, which results in aliasing of image portions (segments) back into the imaging volume. Each of these segments will have a vertical height equal to that of the imaging volume. If the desired imaging volume is other than axial, the same concept will apply except that the “vertical” direction is equivalent to “along the Z-phase encoding direction”. In the particular example shown in FIG. 5, which assumes an exemplary width of a cylindrical phantom and another value for slab thickness, the number of segments will be 7. Only segment marked as “1” is a non-aliased segment where the image information appears in the same position as their source tissue. All segments marked with “SS” show the original location of each segment in the image while segments marked with “Acq” show the correspondingly numbered segments as they appear in the first image set after the scan as a set of axial images where each slice contains multiple axial slices from different locations of the original obliquely excited volume.

The slice encoding field of view is thus adjusted to account for angle θ. The imaging slab thickness depends on both the excitation slab thickness and the angle between the imaging and excitation planes:

THK_{ACQ}=THK_{SS}/cos(θ) [5]

where THK_{ACQ} is acquisition slab thickness and THK_{SS} is slab selection thickness. This new thickness is chosen to avoid irreversible aliasing that would happen if any two image partitions got aliased to the same image location. To preserve the originally planned voxel size, we need to also update the number of slices acquired so that it would increase by the same ratio as the slab thickness:

N′_{Z}=N_{Z}/cos(θ) [6]

(where N′_{Z} is rounded up to an integer and then updated in THK_{Acq} accordingly and where N_{Z} represents the number of slices for the corresponding axial imaging case with the same resolution and N′_{Z} is the new slice number applied in the current method to preserve the resolution and voxel size.

This modification of the acquisition slab thickness and number of slices acquired yields a phase image with preserved contrast which is comparable to standard axial image.

The resulting image is not as radiologically friendly as axial or oblique imaging done in a conventional manner. Therefore, in one embodiment, the image may then be rearranged and re-sliced to restore the usual oblique images look.

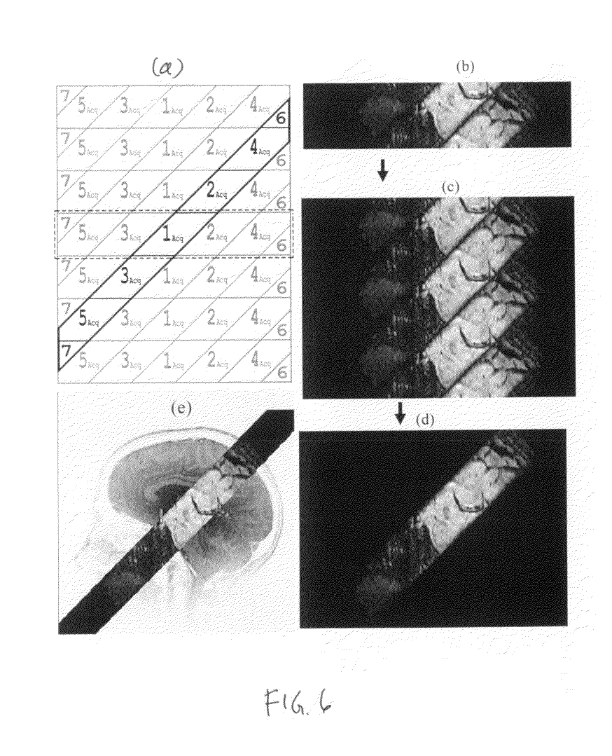

We start with an image as shown in the horizontal imaging area in FIG. 5 and need to reach an image set as shown by the oblique slab selection volume in the same Figure. Exemplary input and output images of this process are shown in FIGS. 6A and 6B respectively.

One solution to this problem is shown in FIG. 6 (sagittal view still) where a few copies of the same acquired image set are stacked on top of each other. The number of copies may be as many as the number of needed image segments. FIG. 6A shows the result of this process where the original slab selection area has been brought back together as shown by the thick lined area while the rest of the schematic shows unwanted repeated aliases. The same is illustrated by a brain image set where the number of image copies was 3 (based on the number of image segments as well as the nature of the anatomy being imaged). After stacking the image copies on top of each other as needed (FIG. 6C), the extra aliases can be removed (FIG. 6D). FIG. 6E shows an overlay of the resulting image on a sagittal brain image from the same volunteer.

The image set may then be interpolated to set the aspect ratio of the image voxels to the appropriate value (in the XZ plane). To be able to collect image slices along straight lines in the XZ plane which are also parallel to the slab selection volume (perpendicular to the slab selection direction), this ratio is set based on the angle θ as follows:

Voxel Height/Voxel Width=tan(θ)

In the case shown we used an angle θ of 45°, which leads to an aspect ratio of 1 (isotropic in XZ). The interpolation process can be done by using zero padding in X, Z up to the desired number of points in both directions as dictated by the above explained aspect ratio. A simpler alternative is to rotate the image set by the same angle θ in the opposite direction to restore the oblique slice alignment. Interpolation to a somewhat isotropic voxel size may be preferred before applying the rotation process.

Considering the Read out gradient axis (X), as shown in the pulse sequence diagram in FIG. 2, the slice selection gradient has been altered so that it has a component in the X direction. Once the “X” slab selection gradient has been flow compensated properly by the end of the third gradient lobe, the read out flow compensation starts fresh with both 0^{th} and 1^{st} moments at null. However, this setup might exacerbate any 2^{nd} moment component (e.g. due to pulsatile flow). Given the thicker slab in 3D imaging and hence the smaller slab selection gradient values, the above problem might be insignificant.

In an alternative embodiment, slice selection is maintained as one simple pulse (standard method for slice selection) while splitting the read out gradients into two components and doing the same to the Z-phase encoding gradients. Thus, the read out gradient is rotated along with the Z-phase encoding gradient, together with respect to the slice selection gradient instead of doing the opposite as explained above. This approach is feasible, but would be more complicated than other embodiments described above.

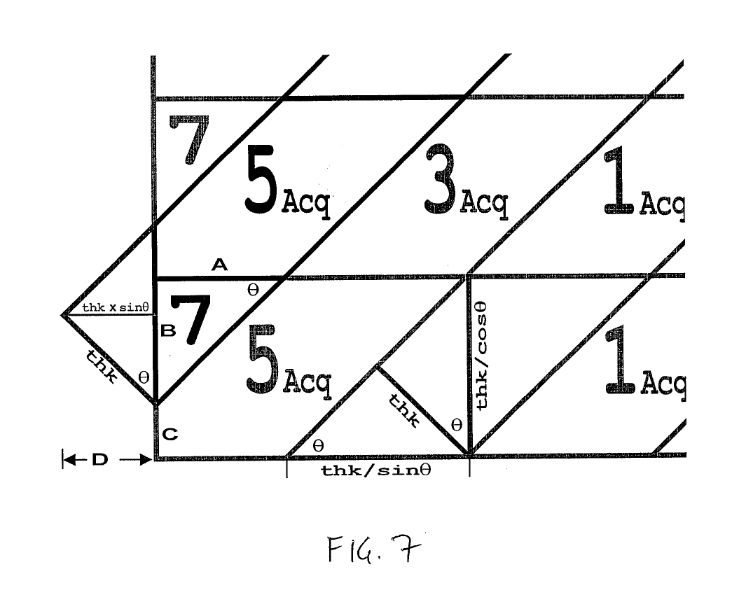

FIG. 7 shows a schematic demonstrating different significant dimensions relating to slab thickness determination and the remapping process. To prevent irreversible aliasing in the Z direction, we have to apply a new value to the Z field of view to match the distance between slab selection volume edges measured in the direction of planned acquisition (vertical line “marked thk/cos θ” along the Z-encoding direction). In FIG. 7:
“thk” is the thickness of slab selection.
“θ” is the angle between the imaging slab and the slice selection slab.
Section width=thk/sin(θ) (defines the width of each aliased image section) □□
N₁=½ FOV_{X}/Section Width (defines the number of segments in one half of the read out field of view)
N₂=N₁+1—remainder (N₁) (same as N1 but rounded up to an integer) (in other words, N₂=integer quotient (½ FOV_{X}/Section Width)+1) (in other words, N₂=round-Up (½ FOV_{X}/Section Width))

Considering the schematic of the acquisition volume shown in FIG. 5 (Marked as Z-Phase Encode) for full schematic view, the count of the segments using the upper side will miss segment “6”, which has no contact with the upper side. This is noted as the added “1” value in the next equation.

N_{segments}=2 N₂+1

Remainder×section width→A

B=A tan(θ)

C=thk/cos(θ)−B

N_{C}=N_{Zacq}×interpolation factor (Z)×C/(thk/cos(θ))

D=thk×sin(θ)

N_{DX}=thk×sin(θ)×N_{X}/FOV_{X}

The image matrix is then padded both on the left and the right side (of the sagittal view) by N_{DX} zeros zone.

New “a” position becomes=(NDX+1)_{X}, N_{C}.

New slice length N′_{X}=N_{X}+N_{DX}

Rearranged slices are mapped starting from point C where the slice is read as vectors (into the page) and where each next vector is located by incrementing both X and Z indices by 1 until the new slice length is reach. (Assuming X, Z=0 at the lower left corner). Next slice starting location is defined by incrementing Z by 1 while decrementing X by 1.

The new value FOV′_{Z} is calculated from:

FOV′_{Z}=thk/cos(θ)

This new imaging volume is shown by the dashed box in FIG. 5 where the thinner tilted box shows the slab selection volume. This value would always be larger than “thk” for any θ>0°. To achieve the same voxel size, the Z phase encoding number is increased, which in turn leads to a proportional increase in scan time. This increase in scan time is justified by the fact that to acquire the same volume axially, we will have to include an even larger sample volume as illustrated by the larger solid box in FIG. 5A. The larger solid box covers all the relevant brain area where the oblique slab traverses the brain. In other situations, this box can be even thicker had image information from the mouth and sinuses been required in this specific case.

In one embodiment, it is preferred to set the slice position parameter (pss) based on the actual slab selection volume while the angle with the main field is defined to the system. If this parameter is otherwise defined by the acquisition volume, an error can happen where the redefined gradients (and hence new angle for slab selection) will cause the volume to rotate around the iso-center rather than around the geometric center of the acquisition slab.

If the user needs to define the pss parameter by the acquisition slab and wishes to still do the slab selection at the center of the same acquisition slab, the new slab position (pss′) can be calculated based on the apparent slab position after the user is done with visual setup of acquisition slab and on the angle between the two volumes:

pss′=pss cos(θ)

This concept is valid for any two volumes in question yet the above equation and details are meant for axial acquisition volume. Another step of calculation might be needed if the acquisition volume has an angle with the axial plane as well. If this becomes an issue, it might be solved by resorting to the alternative pulse sequence design outlined in paragraph [0038] above.

The same pulse sequence changes as well as the incurred benefits are applicable to 2D imaging without the need for image re-slicing/un-aliasing, as no Z-aliasing is applicable to the 2D methods. However, in the case of multiple 2D-Slices, some degree of image transformation, as described above, might be needed to keep the full image stack to proper scale.

As will be apparent to those skilled in the art, various modifications, adaptations and variations of the foregoing specific disclosure can be made without departing from the scope of the invention claimed herein.

1. A three-dimensional magnetic resonance (MR) imaging method, comprising the steps of:
(a) selecting an excitation volume which is not aligned with an acquisition volume, creating an angle between them;
(b) adjusting a slice encoding field of view to account for said angle;
(c) acquiring the MR image; and
(d) reformatting the image to sort aliased portions when present, and to preserve proper scale.

2. The method of claim 1 wherein the alignment of the excitation volume is selected by splitting a slice selection gradient into two components.

3. The method of claim 1 wherein the alignment of the acquisition volume is defined by splitting read-out gradients into two components, and splitting Z-phase encoding gradients into two components.

4. The method of claim 1 wherein the image is reformatted by stacking copies of the image on top of each other in the slice encoding direction, and removing extra aliases.

5. The method of claim 1 wherein the image is reformatted by resetting the aspect ratio of the image.

6. A two-dimensional or three-dimensional magnetic resonance imaging method comprising the steps of:
(a) selecting a frequency encoding direction which is non-orthogonal and non-parallel with the slice selection direction, creating an angle between them;
(b) acquiring the MR image; and
(c) reformatting the image to sort aliased portions when present, and to preserve proper scale.

7. The method of claim 6 which is a three-dimensional method, and further comprising the step of adjusting a slice encoding field of view to account for said angle.

8. The method of claim 6 which is a two-dimensional method.
